(19) United States
(12) Patent Application Publication
(10) Pub. No.: US 2019/0078204 A1
(43) Pub. Date: Mar. 14, 2019

(54) TUBULAR ELECTROSTATIC DEVICE

(71) Applicant: Applied Materials, Inc., Santa Clara, CA (US)

(72) Inventors: Vijay D. PARKHE, San Jose, CA (US); David THOMPSON, San Jose, CA (US)

(21) Appl. No.: 15/702,497

(22) Filed: Sep. 12, 2017

(51) Int. Cl. C23C 16/44; B03C 3/06; B03C 3/49; C01F 7/02; C01B 21/072; C01B 33/12; C01B 21/068; C01G 25/00; C01F 17/00

(52) U.S. Cl. CPC C23C 16/4412; B03C 3/06; B03C 3/49; C01F 7/02; C01F 17/0025; C01B 33/12; C01B 21/068; C01G 25/006; C01B 21/072

(57) ABSTRACT

Embodiments described herein generally pertain to an electrostatic device for use in a process system. Process gas may flow through an aperture formed in a tubular body of a filter. Electrodes disposed within the tubular body create an electric field. The field generated by the electrodes may be utilized to trap contaminate particles flowing through the aperture before entering the processing chamber.

### BACKGROUND

### Field

Embodiments of the present disclosure generally relate to an electrostatic device which may be used to filter particles in a fluid stream.

### Description of the Related Art

Substrate processing methods generally involve exposing a substrate to a process gas in a chamber containing the substrate. A portion of the gas interacts with the substrate surface to form or modify a layer on the substrate. Examples of process methods include physical vapor deposition (PVD), chemical vapor deposition (CVD), plasma enhanced chemical vapor deposition (PECVD), and etching. Contaminants present in the process gas or the process gas delivery system may be deposited on the substrate causing manufacturing defects and reliability issues in the semiconductor device fabricated thereon.

### SUMMARY

In one embodiment, an electrostatic device comprises a body including a flow aperture extending therethrough, one or more electrodes disposed along the sides of the aperture, and one or more power sources coupled to the one or more electrodes.

In another embodiment, a system for processing a substrate, comprises a processing chamber including a gas inlet port, a gas source, and a filter. The filter further comprises a body including a flow aperture extending therethrough, two or more electrodes disposed along the sides of the flow aperture, and one or more power sources coupled to the two or more electrodes.

In yet another embodiment, a electrostatic device assembly comprises a body including an aperture therethrough, two or more electrodes disposed within the body, one or more power sources coupled to the two or more, and end connections attached to the body.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of their scope, and the disclosure hereof may admit to other equally effective embodiments.

FIG. 1 is a schematic, cross-sectional view of an exemplary processing chamber.

FIG. 2 is a schematic illustration of a electrostatic device according to one embodiment.

FIG. 3 is a schematic, cross sectional view of a filter according to one embodiment.

FIG. 4 is a schematic of a processing system according to one embodiment.

FIGS. 5A-5E are exemplary cross-sections of an electrostatic device according to certain embodiments.

To facilitate understanding, identical reference numerals have been used, where possible, to designate identical elements that are common in the figures. It is contemplated that elements and features of one embodiment may be beneficially incorporated in other embodiments without further recitation of the features thereof.

### DETAILED DESCRIPTION

Embodiments described herein generally pertain to an electrostatic device for use in a process system. Process gas may flow through an aperture formed in a tubular body of a filter. Electrodes disposed within the tubular body create an electric field. The field generated by the electrodes may be utilized to trap contaminate particles flowing through the aperture before entering the processing chamber.

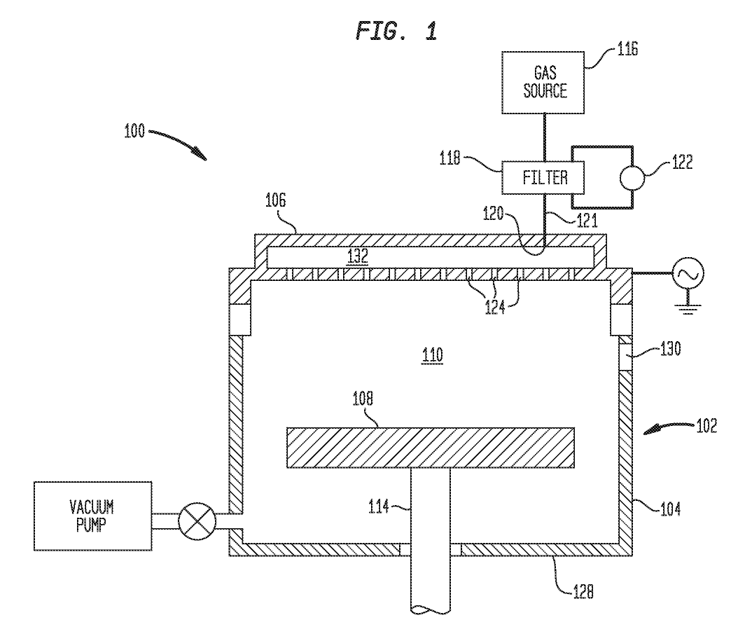

FIG. 1 is schematic cross-sectional view of an exemplary processing system 100. It is understood that the embodiments may be practiced in conjunction with any process system that necessitates introducing a gas into a chamber. The processing system 100 includes a process chamber 102 connected to a gas source 116. The process chamber 102 has sidewalls 104, a bottom 128, and a lid 106 that partially define a processing volume 110. A substrate support 108 is disposed within the process chamber 102 and supported therein on the end of a shaft 114 extending inwardly of the process chamber. A substrate (not shown) is placed on the substrate support 108 though a port 130 in the sidewall 104.

A process gas from the process gas source 116 is introduced though a gas inlet line 121 into a gas dispersion region 132 of the process chamber 102 through a gas inlet port 120. The process gas source 116 may be any source suitable for use in the processing system such as a pressurized tank or boule, a gas formed by passing a carrier gas through a precursor material, or a source connected to a manufacturing facility gas line. An electrostatic device 118 is disposed in the gas inlet line 121 upstream of the gas inlet port 120. In certain embodiments, the electrostatic device 118 may be disposed at the gas inlet port 120. In certain embodiments, the electrostatic device may be disposed within the gas source in a location where gas is flowing toward a process gas use location. The process gas flows from the process gas source 116, through the gas inlet line 121 and electrostatic device 118, and into the gas dispersion region 132 via the gas inlet port 120 of the chamber 102. The process gas enters the process volume 110 from the gas dispersion area 132 through openings 124. The electrostatic device 118 is coupled to a power source 122 to electrostatically interact with the process gas flowing therein.

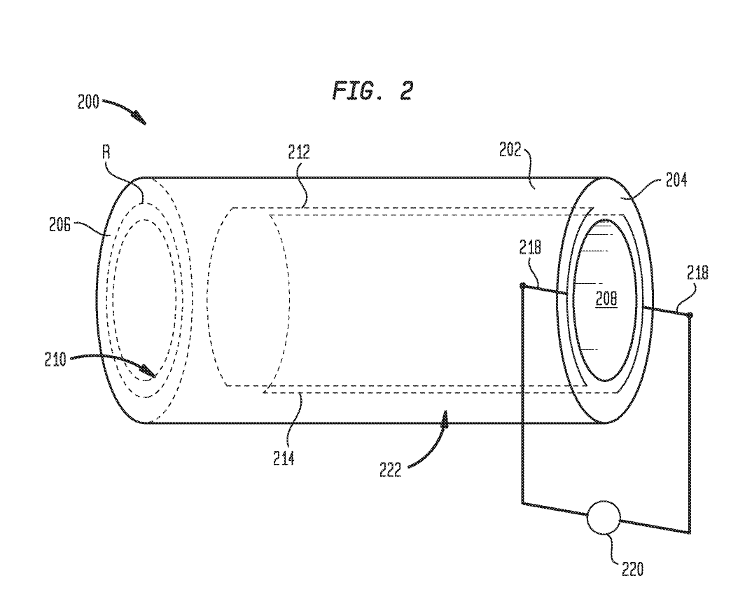

FIG. 2 is a schematic view of an electrostatic device according to one embodiment. In the embodiment shown in FIG. 2, the electrostatic device 200 has a tubular body 202 terminating in opposed end surfaces 204, 206, and a circumferential outer surface 222, and an aperture 208 extending through the tubular body 202 bounded by a circumferential an inner surface 210. The tubular body is formed primarily of a non-conducting material, for example a ceramic material. In certain embodiments, the material may be alumina, alumina nitride, quartz, silicon nitride, yttria-stabilized zirconia (YSZ), yttrium aluminum garnet (YAG), or materials known in the art as High Performance Material (HPM). However, other materials are contemplated. Electrodes 212 and 214 are disposed within the tubular body 202. In FIG. 2, the two electrodes extend along a radius R of the aperture 208. The electrostatic device 200 may have a different number of electrodes, but at least one electrode is disposed therein. In certain embodiments, more than two electrodes, such as three or four or eight, may be disposed within the tubular body. Any number of electrodes capable of forming an electric charge or field across the aperture 208 or the inner surface 210 thereof may be utilized.

The electrodes 212 and 214 are disposed at different locations in the electrostatic device 200. In certain embodiments, electrodes 212 and 214 may be disposed at differing depths within the tubular body, for example, inwardly of the tubular body from the aperture 208 between 50 microns and 350 microns from the inner surface 210 of the tubular body. In further embodiments, the electrodes may be disposed with one surrounding the other. In still further embodiments, the one or more electrodes may define the inner surface 210 of the aperture 208. In still further embodiments, the electrodes may be disposed on the outer surface of the tubular body 202. Any configuration of electrodes suitable for forming the above described electric field or charge may be utilized.

The electrodes 212 and 214 are coupled to a power source 220 via terminals 218. The power source 200 imposes a voltage difference onto the electrodes. The voltage applied may have a range, for example, of up to 4000 volts. Multiple power sources may be coupled to the electrodes. A different voltage may be provided to each electrode individually. In certain embodiments, the voltages may have opposite polarity. The electrodes may be biased to be monopolar or bipolar. In further embodiments wherein multiple pairs of electrodes are utilized, the voltage difference imposed between each electrode pair may be equal or may be different.

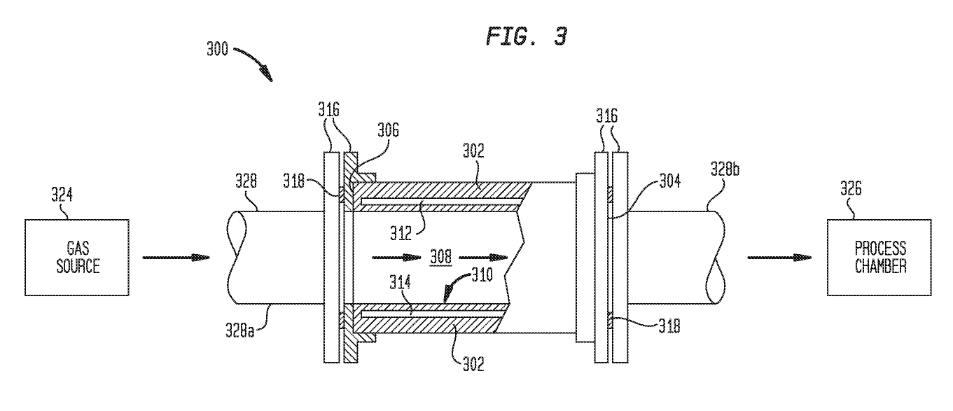

FIG. 3 is an illustrative, partially in cross-section, schematic of an electrostatic device utilized as a filter. The filter 300 is positioned in a gas supply conduit 328, such as inlet line 121 of FIG. 1, disposed between a gas source 324, such as gas source 116 of FIG. 1, and a process chamber 326, such as process chamber 102 of FIG. 1. A process gas flows from the gas source 324 to the process chamber 326 though an aperture 308 extending through a tubular body 302 of the filter 300 disposed in the gas supply conduit 328. In FIG. 3, the aperture 308 and the gas supply conduit 328 have substantially equal internal diameters. The internal diameter of the aperture 308 and the gas supply conduit 328 may have different dimensions.

In the embodiment of FIG. 3, the filter 300, also referred to as a cartridge herein, is connected between first and second segments 328a, 328b of the gas supply conduit 328 by end connections 316 located at opposed faces 304 and 306 of the tubular body 302. Here, the end connections 316 are flanges on the opposed end faces 304,306 of the tubular body 302 and mating flanges on the mating ends of the gas supply line portions 328a, 328b. A seal 318 is disposed between the flanges to prevent leakage of the process gas from the interface of gas supply line segments 328a, 328b and filter 300 ends 304, 306. The end connections 316 allow the tubular filter to be removed for cleaning or replacement thereof, either as a part of scheduled maintenance of the process chamber 326, or in the event of a particle excursion (increase in particles) in the process chamber 326. Other types of end connections may be used to connect the tubular filter 300 to the gas supply line such as brazing, couplings, diffusion bonding, seals, ceramic welding, or any other suitable connection thereof into the gas supply conduit 328. In certain embodiments, a housing which is integral to the gas supply conduit 328 may contain the tubular filter 300. The tubular filter 300 may also be configured to be integral to the gas supply conduit 328 wherein the tubular filter 300 is not removable, or configured as an insert or cartridge which is located within a housing along the flow direction of the gas supply conduit 328.

Electrodes 312 and 314 are disposed within the tubular body 302. The electrodes have a thickness in a radius direction of the tubular body 302 of, for example, between 100 μm to 1 mm. Electrodes 312 and 314 are coupled to a power source (not shown). The power source imposes a voltage on the electrodes. Electrically charged contaminant particles in the process gas interact with an electric field created by the charged electrodes and are attracted electrostatically toward one of the electrodes 312, 314, and these particles then become attached to the inner surface 310 of the aperture 308, thus preventing the contaminant particles from entering the processing chamber 326 and depositing on a substrate or the interior surfaces of the process chamber. The inner surface 310 may have a roughened finish, such as an average surface roughness in a range of 8 Ra to 64 Ra, to increase capture of particles thereon. A buildup of contaminant particles on the inner surface 310 of the tubular body over a period of time will reduce the effectiveness of the filter. The filter may be cleaned or replaced to remove the buildup of contaminate particles.

Valves may be disposed along the gas supply conduit 328 upstream and downstream of the filter 300 to selectively isolate the filter 300. In order to perform maintenance on the filter 300, the valves are closed to isolate the filter 300 from the process gas source 324 and the process chamber 326. The filter 300 may then be removed from the gas supply line 328 in order to remove any contaminants along the inner surface 310 thereof. This may be accomplished, for example, by removing the existing filter 300 and installing the same filter 300 after cleaning, if desired, or replacing the filter 300 with a different identical filter 300. Upon the completion of the maintenance activity, the valves will then be reopened, thus reintroducing the process gas flow through the filter.

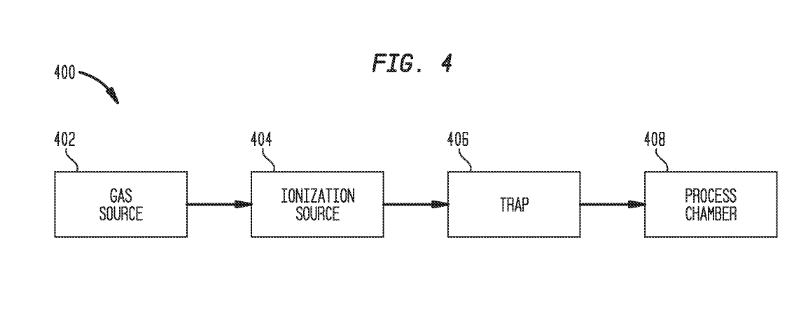

FIG. 4 is a schematic of a processing system practiced with the electrostatic device described herein. The processing system 400 comprises an ionization source 404 and filter 406 disposed between a gas source 402 and a processing chamber 408. The gas source 402 and the processing chamber 408 may be like those described in FIG. 1. The filter 404 is like the filter 300 of FIG. 3. In order to increase capture efficiency, the ionization source 404 is provided to ionize a gas stream flowing therethrough. The ionization source 404 may be any source capable of causing a charge to form on particles in the gas stream such as a charge gun, an ionizer, or a radioactive source. Gas is flowed from the gas source 402 to the processing chamber 408. The gas and particles therein are ionized by the ionization source 404 before flowing through the filter 406. An electric field created by the charged electrodes embedded within the filter 406 attracts the charged contaminant particles to one of the electrodes and attach the internal surface of the aperture formed therethrough.

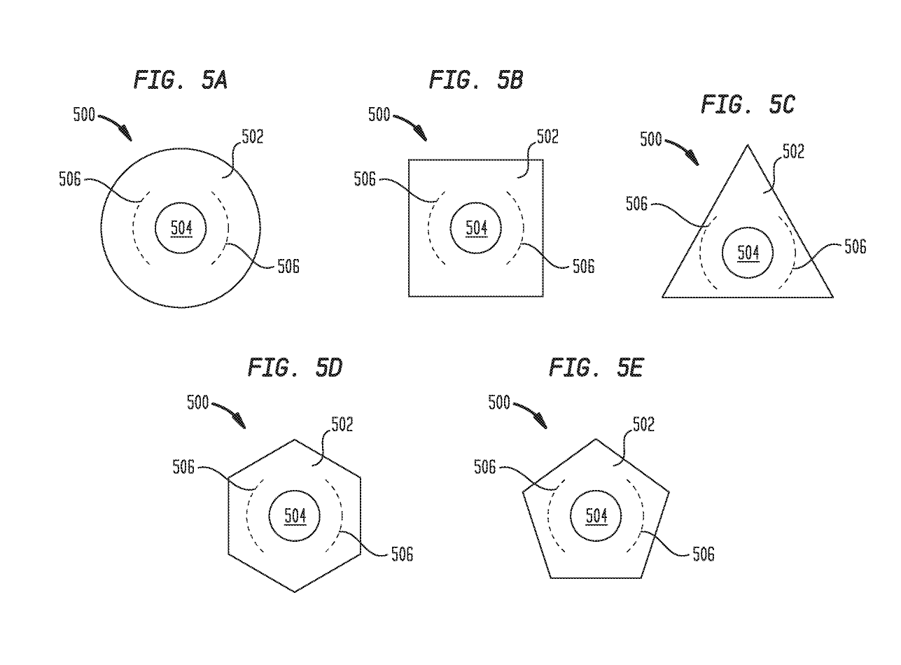

FIGS. 5A-5E are schematic cross-sectional views of additional geometries of the cross section of the electrostatic device 500. The geometry of the body 502 may be of any suitable shape. Electrodes 506 (indicated in dashed line outline) are here embedded within the tubular body 502 as shown, but may alternatively be disposed on the outer or inner surfaces thereof, or disposed in recesses extending inwardly of the inner and outer surfaces thereof. A flow opening 504 extends through the body 502, between opposed electrodes 506 therein or thereabout. In certain embodiments, the tubular body 502 has a right annular cross-section, although an ovoid cross-section is also contemplated. In certain embodiments, the filter body has a polygonal cross-section, such as a 3, or 4, or 5, or 6, or more sided polygon. An exemplary open of a circular cross-section is shown in FIGS. 5A-5E but other geometries have been contemplated, such as square, triangular, or rectangular.

It is contemplated that the embodiments herein may also be practiced in other manners within a processing system. For example, the electrostatic device may be utilized as a electrostatic chuck. Further, arrays of the electrostatic device may be arranged and controlled individually to optimize electromagnetic fields.

While the foregoing is directed to embodiments of the present disclosure, other and further embodiments of the disclosure may be devised without departing from the basic scope thereof, and the scope thereof is determined by the claims that follow.

What is claimed is:

1. An electrostatic apparatus comprising:
a body including a flow aperture extending therethrough;
one or more electrodes disposed along the sides of the aperture; and
one or more power sources coupled to the one or more electrodes.

2. The apparatus of claim 1, wherein the body comprises a ceramic material.

3. The apparatus of claim 2, wherein the ceramic material further comprises alumina, aluminum-nitride, quartz, silicon nitride, yttria-stabilized zirconia, yttrium aluminum garnet, or high performance materials (HPM).

4. The apparatus of claim 1, wherein the body is annular in section.

5. The apparatus of claim 1, wherein the electrodes are located between 50 micron and 350 micron from an inner surface of the body defined by the wall of the flow aperture.

6. A system for processing a substrate, comprising:
a processing chamber including a gas inlet port;
a gas source; and
a filter, the filter further comprising:
a body including a flow aperture extending therethrough;
two or more electrodes disposed along the sides of the flow aperture; and
one or more power sources coupled to the two or more electrodes.

7. The system of claim 6, wherein the body comprises a ceramic material.

8. The system of claim 7, wherein the ceramic material further comprises alumina, aluminum-nitride, quartz, silicon nitride, yttria-stabilized zirconia, yttrium aluminum garnet, or high performance material (HPM).

9. The system of claim 6, wherein the body is annular in section.

10. The system of claim 6, wherein the filter further comprises opposed end connections.

11. The system of claim 10, wherein the opposed end connections comprise flanges, couplings, brazing, bonding, ceramic welding, seals, or a combination thereof.

12. The system of claim 6, where in the electrodes have a thickness between 1 μm and 1 mm.

13. The system of claim 6, further comprising an ionization source.

14. The system of claim 6, wherein the filter is disposed within a flow line extending between the gas source and the processing chamber.

15. The system of claim 6, wherein the filter is disposed within the gas inlet port.

16. The system of claim 6, wherein the filter is disposed within the gas source.

17. An electrostatic device assembly comprising:
a body including an aperture therethrough;
two or more electrodes disposed within the body;
one or more power sources coupled to the two or more electrodes; and
end connections attached to the body.

18. The assembly of claim 17, wherein the end connections comprise flanges, couplings, brazing, bonding, ceramic welding, seals, or a combination thereof.

19. The assembly of claim 17, wherein the body comprises a ceramic material.

20. The assembly of claim 19, wherein the ceramic material further comprises alumina, aluminum-nitride, quartz, silicon nitride, yttria-stabilized zirconia, yttrium aluminum garnet, or high performance materials (HPM).
